(19) United States
(12) Patent Application Publication
(10) Pub. No.: US 2005/0212000 A1
(43) Pub. Date: Sep. 29, 2005

(54) Method for manufacturing light emitting device, and electronic device

(75) Inventors: Tsunenori Suzuki, Yokohama (JP); Satoshi Seo, Kawasaki (JP); Ryoji Nomura, Yamato (JP)

Correspondence Address: COOK, ALEX, McFARRON, MANZO,;CUMMINGS & MEHLER, LTD., SUIT 2850, 200 WEST ADAMS STREET, CHICAGO, IL, 60606, US

(73) Assignee: Semiconductor Energy Laboratory Co., Ltd.

(21) Appl. No.: 11/080,149

(22) Filed: Mar. 15, 2005

(30) Foreign Application Priority Data
Mar. 26, 2004 (JP) 2004-091938

(51) Int. Cl. H01L 29/22

(52) U.S. Cl. 257/94

(57) ABSTRACT

It is an object of the present invention to provide a method for manufacturing a light-emitting device which can reduce the increase of power consumption generated by a stabilization process of the lowering of light-emitting luminance with the passage of emission time. The method for manufacturing the light-emitting device has a step for applying reverse voltage after a process for stabilizing the lowering of light-emitting luminance. The process for stabilizing the lowering of light-emitting luminance is not limited in particular, but a process for applying forward voltage can be given as the process, for example.

### BACKGROUND OF THE INVENTION

1. Field of the Invention

The present invention relates to a method for manufacturing a semiconductor device. More specifically, the invention relates to a process for stabilizing the lowering of light luminance.

2. Description of the Related Art

A light-emitting device utilizing light emitted from an electroluminescent element (a light-emitting element) attracts attention as a low power consumption display device having a wide viewing angle.

In the meantime, a light-emitting element shows a phenomenon that light-emitting luminance is lowered with the passage of emission time when light is emitted by continuously applying a certain amount of current. Such the lowering of light-emitting luminance is drastically at the beginning of a passage of emission time. The decrease is gradually stabilized after a certain period of time.

Therefore, in manufacturing a light-emitting device, a process for stabilizing the lowering of light-emitting luminance with the passage of emission time is sometimes performed. For example, a method for manufacturing an organic electroluminescence element which is aged in the current density from 5 to 1,000 times current density when driving is disclosed in Patent Document 1 (Patent Document 1: Japanese Patent Application Laid-open No. 8-185979).

However, a light-emitting element also shows a phenomenon that voltage required to apply a certain amount of current increases with the passage of emission time. Thus, there is a problem that power consumption of a light-emitting device increases by the manufacturing method described in the Patent Document 1.

### SUMMARY OF THE INVENTION

It is an object of the present invention to provide a method for manufacturing a light-emitting device which can reduce the increase of power consumption generated by a process for stabilizing the lowering of light-emitting luminance with the passage of emission time.

One feature of the invention is that a method for manufacturing a light-emitting device includes a process for applying reverse voltage after a process for stabilizing the lowering of light-emitting luminance is performed to a light-emitting element which shows rectifying action. There is no limitation on the process for stabilizing the lowering of light-emitting luminance in particular, but a process for applying forward voltage is given as the process, for example.

Another feature of the invention is that the method for manufacturing the light-emitting device includes a process for applying voltage in a direction that current flows easily (that is, forward voltage), and further, applying voltage in a direction that current does not flow easily (that is, reverse voltage).

Another feature of the invention is that the method for manufacturing the light-emitting device includes a process for applying reverse voltage after a process for stabilizing the lowering of light-emitting luminance is performed to the light-emitting element which is constituted by overlapping a pair of electrodes with a light-emitting layer therebetween and which shows rectifying action. There is no limitation on the process for stabilizing the lowering of light-emitting luminance in particular, but a process for applying forward voltage is given as the process, for example.

According to the invention, a light-emitting device in which the increase of power consumption generated by a stabilization process is reduced, in addition to stabilizing the lowering of light-emitting luminance with the passage of emission time.

These and other objects, features and advantages of the present invention will become more apparent upon reading of the following detailed description along with the accompanied drawings.

### BRIEF DESCRIPTION OF THE DRAWINGS

FIGS. 1A and 1B are explanatory views of a method for manufacturing a light-emitting device according to the present invention;

FIGS. 2A to 2C are explanatory views of a method for manufacturing a light-emitting device according to the invention;

FIGS. 3A to 3C are explanatory views of a method for manufacturing a light-emitting device according to the invention;

FIG. 4 is a schematic top view of a light-emitting device according to the invention;

FIGS. 5A to 5C are explanatory views of a circuit for driving a pixel portion of a light-emitting device according to the invention;

FIG. 6 is a top view of a pixel portion of a light-emitting device according to the invention;

FIG. 7 is a top view of a pixel portion of a light-emitting device according to the invention;

FIGS. 8A to 8C are electronic devices to which the invention is applied;

FIG. 9 is a view showing a measurement result related to a relative value of an integral value of an emission spectrum at a current of 1 mA and a relative value of voltage required to apply current of 1 mA; and

FIG. 10 is an explanatory view of a specific mode of a light-emitting layer 212 included in FIG. 3C.

### DETAILED DESCRIPTION OF THE INVENTION

Embodiment modes according to the present invention are described in detail with reference to the drawings. However, it is easily understood by those who are skilled in the art that embodiments and details herein disclosed can be modified in various ways without departing from the purpose and the scope of the present invention. Therefore, it should be noted that the description of embodiment modes to be given below should not be interpreted as limiting the present invention.

[Embodiment Mode 1]

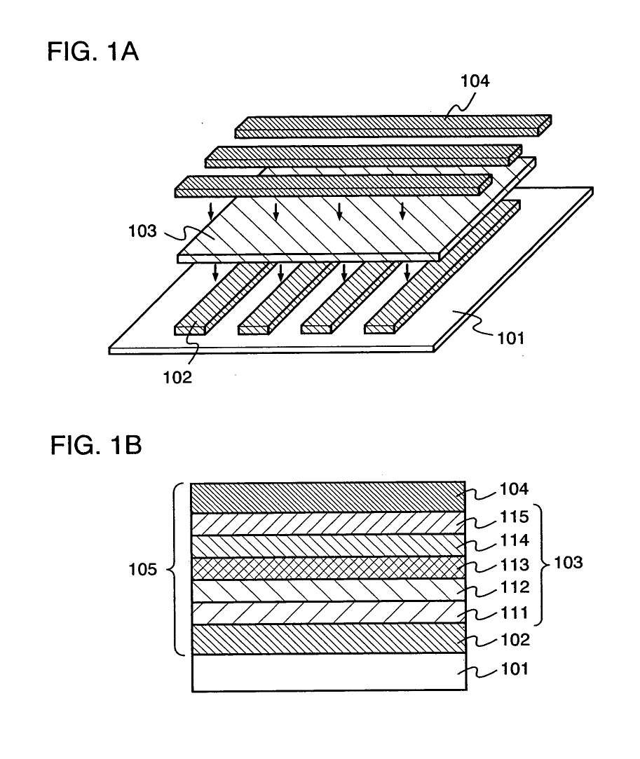

In this embodiment mode, a method for manufacturing a light-emitting device including a light-emitting element 105 constituted by overlapping a first electrode 102 and a second electrode 104 with a light-emitting layer 103 therebetween is described with reference to a perspective view of FIG. 1A and a cross-sectional view of FIG. 1B. Note that FIG. 1B shows a cross-sectional view of one of the plurality of the light-emitting elements manufactured over a substrate 101. In the light-emitting element 105, a hole injected from the first electrode 102 to the light-emitting layer 103 and an electron injected from the second electrode 104 to the light-emitting layer 103 are recombined in the light-emitting layer 103 to form an exciton. Light emits when the exciton returns to a ground state. That is, the first electrode 102 serves as an anode and the second electrode 104 serves as a cathode.

The first electrode 102 is formed over the substrate 101. A conductive film is formed, and the conductive film is processed so that a plurality of conductive films extended either in rows or in columns parallel to each other, thereby the first electrode 102 is formed. Here, there is no limitation on the materials of the first electrode 102 in particular, but the first electrode 102 is preferably formed by using a substance having high work function. In particular, gold (Au), platinum (Pt), nickel (Ni), tungsten (W), chromium (Cr), molybdenum (Mo), iron (Fe), cobalt (Co), copper (Cu), palladium (Pd) or the like can be used for the first electrode 102 other than indium tin oxide (ITO), indium tin oxide containing silicon oxide or indium oxide containing 2% to 20% zinc oxide. Note that a method for forming the first electrode 102 is not limited in particular, and for example, the first electrode 102 can be formed by employing a sputtering method, a vapor deposition method or the like.

Next, the light-emitting layer 103 is formed over the first electrode 102. The light-emitting layer 103 is formed by sequentially stacking a first layer 111, a second layer 112, a third layer 113, a fourth layer 114 and a fifth layer 115, as shown hereinafter.

First, the first layer 111 is formed over the first electrode 102. Here, there is no limitation on the materials of the first layer 111 in particular, but the first layer 111 is preferably formed by using a substance which can assist in injecting a hole from the first electrode 102 to the light-emitting layer 103. Specifically, the first layer 111 can be formed by using metal oxide such as molybdenum oxide (MoOx), vanadium oxide (VOx), ruthenium oxide (RuOx), tungsten oxide (WOx), or manganese oxide (MnOx), besides a compound of phthalocyanine system such as phthalocyanine (abbreviated H₂Pc) or copper phthalocyanine (CuPc). Note that a method for manufacturing the first layer 111 is not limited in particular, and for example, the first layer 111 can be formed by employing a sputtering method, a vapor deposition method or the like.

Next, the second layer 112 is formed over the first layer 111. Here, there is no limitation on the materials of the second layer 112 in particular, but the second layer 112 is preferably formed by using a substance which transports a hole easily. In addition, a substance which transports a hole easily, and furthermore, which can prevent an electron from flowing is more preferable to be used. Specifically, the second layer 112 can be formed by using a compound of aromatic amine system (namely, having a bond of benzene ring-nitrogen) such as 4,4′-bis[N-(1-naphthyl)-N-phenyl-amino]-biphenyl (abbreviated α-NPD), 4,4′-bis[N-(3-methylphenyl)-N-phenyl-amino]-biphenyl (abbreviated TPD), 4,4′,4″-tris(N,N-diphenyl-amino)-triphenylamine (abbreviated TDATA), or 4,4′,4″-tris[N-(3-methylphenyl)-N-phenyl-amino]-triphenylamine (abbreviated MTTATA). Note that a method for manufacturing the second layer 112 is not limited in particular, and for example, the second layer 112 can be formed by employing a vapor deposition method or the like.

Next, the third layer 113 is formed over the second layer 112. Here, there is no limitation on the materials of the third layer 113 in particular, but the third layer 113 is preferably formed by using a substance having high light-emitting properties (a light-emitting substance). Note that, when the light-emitting substance is preferably dispersed in a layer, the third layer 113 may be formed by mixing the light-emitting substance and a substance having a higher energy gap of HOMO level and LUMO level than the light-emitting substance so that the light-emitting substance is dispersed. Note that one or both of the light-emitting substance and the substance having a higher energy gap than the light-emitting substance is preferably a substance which can transport an electron and a hole easily. 4-dicyanomethylene-2-methyl-6-[2-(1,1,7,7-tetramethyljulolidine-9-yl)ethenyl]-4H-pyran (abbreviated DCJT), 4-dicyanomethylene-2-t-butyl-6-[2-(1,1,7,7-tetramethyljulolidine-9-yl)ethenyl]-4H-pyran (abbreviated DCJTB), Periflanthene, 2,5-dicyano-1,4-bis[2-(10-methoxy-1,1,7,7-tetramethyljulolidine-9-yl)ethenyl]benzene, N,N′-dimethylquinacridone (abbreviated DMQd), coumarin 6, coumarin 545T, tris(8-quinolinolato)aluminum (abbreviated Alq₃), 9,9′-biantolyl, 9,10-diphenylanthracene (abbreviated DPA), 9,10-bis(2-naphthyl)anthracene (abbreviated DNA) or the like can be given as a specific example of the light-emitting substance. In addition to this, a metal complex or the like containing platinum which is a third transition element, iridium or the like as a central metal can be used.

Next, the fourth layer 114 is formed over the third layer 113. Here, there is no limitation on the materials of the fourth layer 114 in particular, but the fourth layer 114 is preferably formed by using a substance which transports an electron easily. Moreover, the fourth layer 114 is preferably formed by using a substance which transports an electron easily, and further, can prevent a hole from flowing. A metal complex or the like having a quinoline skeleton or a benzoquinoline skeleton such as tris(8-quinolinolato)aluminum (abbreviated Alq₃), tris(5-methyl-8-quinolinolato)aluminum (abbreviated Almq₃), bis(10-hydroxybenzo[h]quinolinato)beryllium (abbreviated BeBq₂), or bis(2-methyl-8-quinolinolato)-4-phenylphenolate-aluminum (abbreviated BAlq) can be used as a specific example. Note that a method for manufacturing the fourth layer 114 is not limited in particular, and for example, the fourth layer 114 can be formed by employing a vapor deposition method or the like.

Next, the fifth layer 115 is formed over the fourth layer 114. Here, there is no limitation on the materials of the fifth layer 115 in particular, but the fifth layer 115 is preferably formed by using a substance which can assist in injecting an electron from the second electrode 104 to the light-emitting layer 103. Specifically, a compound or the like of an alkali metal or an alkali earth metal such as lithium fluoride (LiF), cesium fluoride (CsF), or calcium fluoride (CaF₂) can be used. Note that a method for manufacturing the fifth layer 115 is not limited in particular, and for example, the fifth layer 115 can be formed by employing a vapor deposition method or the like.

The second electrode 104 is formed over the light-emitting layer 103 formed as described above. A conductive film is formed, and the conductive film is processed so that a plurality of conductive films extended parallel are formed to intersect with the first electrode 102, thereby the second electrode 104 is formed. Here, there is no limitation on the materials of the second electrode 104 in particular, but the second electrode 104 is preferably formed by using a material having low work function. Specifically, aluminum or the like containing an alkali metal such as lithium (Li) or an alkali earth metal such as magnesium can be used. Moreover, as in this embodiment mode, the substance having high work function such as ITO described above can be used as a substance which forms the second electrode 104 by providing the layer (the fourth layer 114) formed by containing the substance which can assist in injecting the electron from the second electrode 104 to the light-emitting layer 103. Note that a method for manufacturing the second electrode 104 is not limited in particular, and for example, the second electrode 104 can be formed by employing a vapor deposition method or the like. Furthermore, one or both of the first electrode 102 and the second electrode 104 is preferably formed by selecting the thickness of the electrode and the substance so as to be able to transmit visible light.

As described above, a plurality of light-emitting elements 105 arranged in rows and in columns can be manufactured over the substrate 101. Note that the light-emitting element 105 is an element which shows rectifying action.

Next, a process for stabilizing the lowering of luminance is performed by applying forward voltage to the light-emitting element 105 manufactured over the substrate 101 for a certain period of time. Here, there is no limitation on processing time in particular, but the process is preferably performed till luminance at a certain amount of applied current becomes from 80% to 95% of luminance obtained before the process (namely, the initial value of luminance). Specifically, it is preferable that the forward voltage is applied for from 6×10¹ to 6×10⁵ seconds continuously. Note that a method for stabilizing the lowering of luminance is not limited to an object shown here, and other method for a process may be employed.

Next, a process for applying reverse voltage to the light-emitting element 105 manufactured over the substrate 101 is performed for a certain period of time. By this process, drive voltage increased by the process for stabilizing the lowering of luminance can be decreased. Here, there is no limitation on processing time in particular, but the reverse voltage is preferably applied until it becomes 30 to 80% of the voltage which was required to apply a certain amount of current. Specifically, it is preferable that reverse voltage is applied for from 6×10¹ to 6×10⁵ seconds continuously.

As described above, a light-emitting device which can control an emission state or a non-emission state of the light-emitting element 105 by a passive driving.

Note that, in the light-emitting device manufactured in this embodiment mode, an electrode for injecting a hole to the light-emitting layer is formed in advance, and an electrode for injecting an electron to the light-emitting layer is formed later; however, a step for manufacturing the light-emitting element is not limited to this. For example, the electrode for injecting an electron to the light-emitting layer may be formed in advance, and the electrode for injecting a hole, to the light-emitting layer may be formed later. Moreover, a layer structure of the light-emitting layer is also not limited to an object shown in this embodiment mode. For example, in the case of using a substance which has high light-emitting properties and transports an electron easily like tris(8-quinolinolato)aluminum (abbreviated Alq₃), the third layer 113 and the fourth layer 114 are not necessarily formed separately like the light-emitting element 105. Furthermore, for example, in the case or the like of using a substance which can assist in injecting a hole from the first electrode 102 to the light-emitting layer 103 and transports a hole easily like a high molecular weight material in which polystyrenesulphonic acid (PSS) and polyethylene dioxythiophene (PEDOT) are mixed, the first layer 111 and the second layer 112 are not necessarily formed separately like the light-emitting element 105. That is, the number of layers which constitutes the light-emitting layer may be adjusted arbitrarily depending on the classification or the like of a substance used for forming the light-emitting layer. An inorganic material may be used for forming the light-emitting layer other than a low molecular weight or high molecular weight organic material. In addition, the thickness of a layer which constitutes the light-emitting layer may be also adjusted arbitrarily.

Moreover, the light-emitting device manufactured as described above may be sealed so that the light-emitting device 105 does not deteriorate due to moisture or the like included in the air. Furthermore, a process for stabilizing the lowering of light-emitting luminance depending on the passage of emission time or a process for applying reverse voltage performed thereafter may be performed.

The light-emitting device manufactured as described above is an object in which the lowering of light-emitting luminance depending on the passage of emission time is stabilized, and further, the increase of power consumption generated by the stabilization process is decreased.

[Embodiment Mode 2]

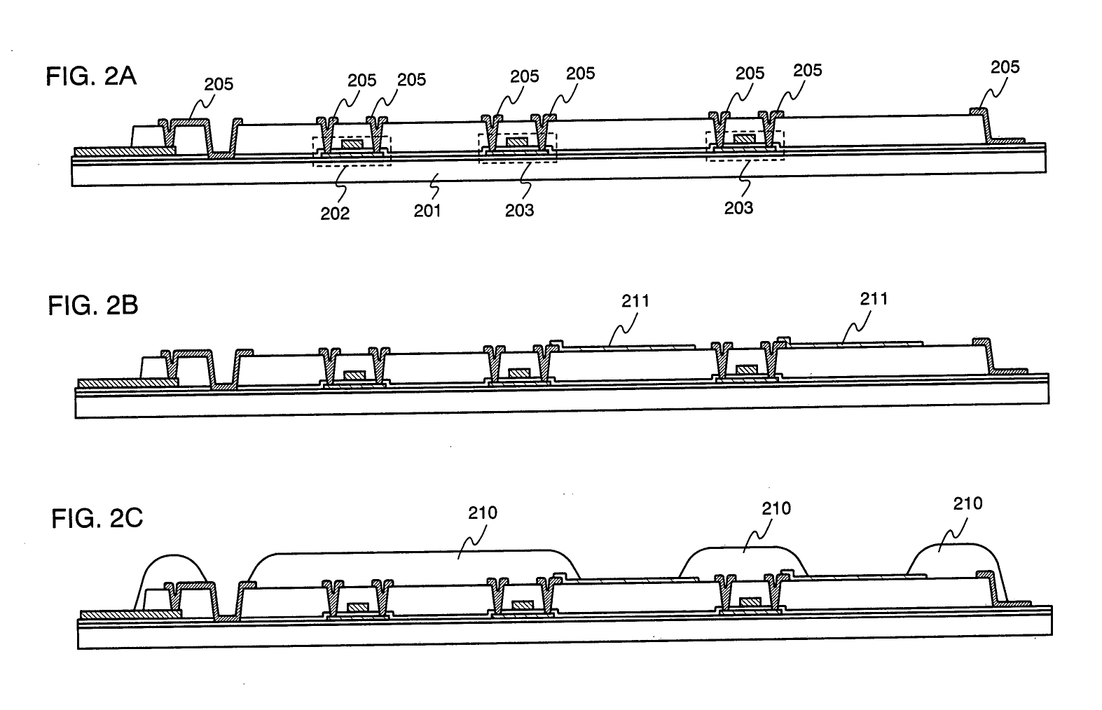

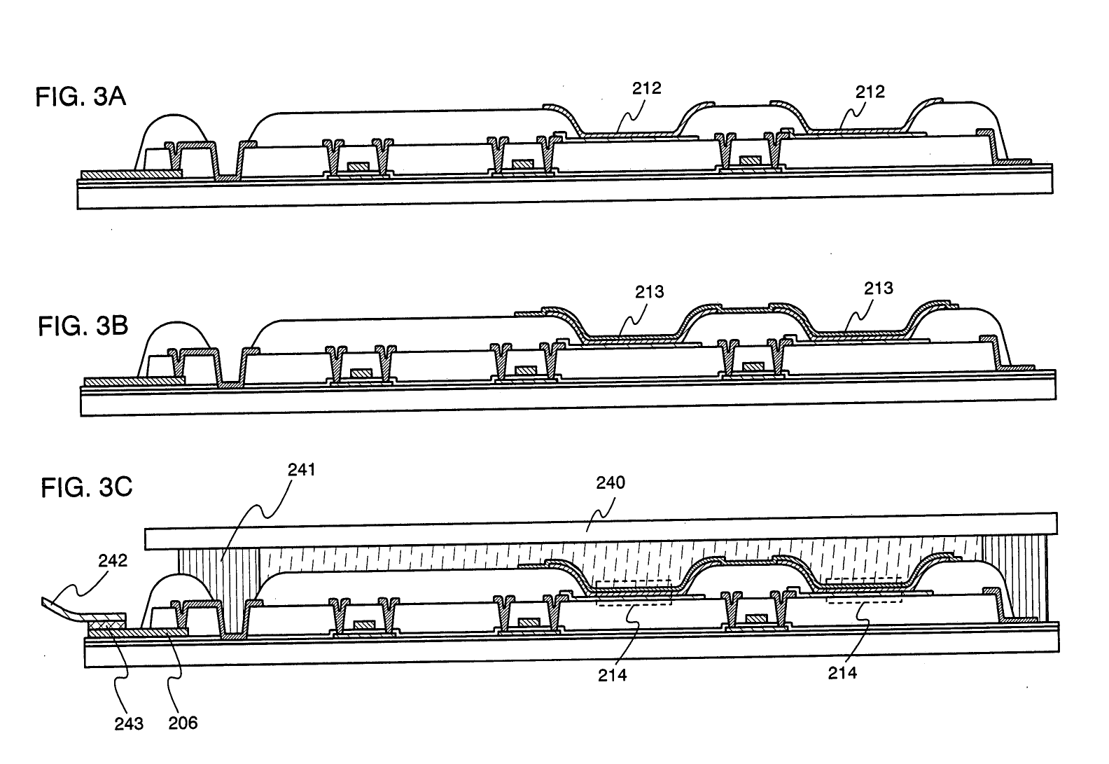

According to a method for manufacturing a light-emitting device of the present invention, an active matrix light-emitting device or the like other than the passive type light-emitting device as shown in Embodiment Mode 1 can be manufactured. In this embodiment mode, a method for manufacturing an active matrix light-emitting device by applying the invention is described with reference to FIGS. 2A to 3C.

Transistors 202 and 203, a wiring 205 and the like for transmitting a signal to the transistor are formed over a substrate 201. Note that, in FIG. 2A, the transistor 202 is a transistor included in a gate signal driver circuit portion, and the transistor 203 is a transistor included in a pixel portion.

Next, a light-emitting element 214 constituted by overlapping a first electrode 211 and a second electrode 213 with a light-emitting layer 212 therebetween is manufactured. A method for manufacturing the light-emitting element 214 is described hereinafter. However, a structure of the light-emitting element 214 is not limited to an object to be given below.

The first electrode 211 is formed so as to connect the part of the first electrode 211 and the part of the wiring 205 which reaches the transistor 203 through an insulating layer which covers the transistor 203. Here, there is no limitation on the materials of the first electrode 211 in particular, but in this embodiment mode, the first electrode 211 is formed by using a substance having low work function which is same as the second electrode 104 in Embodiment Mode 1.

Next, a bank layer 210 which separates each light-emitting element is formed. The bank layer 210 is preferably formed to have a shape in which the radius of curvature is preferably varied continuously. Moreover, in an opening portion, the first electrode 211 is set to be exposed. Note that there is no limitation on a substance which forms the bank layer 210 in particular, and for example, acryl, polyimide, siloxane (a substance in which a skeletal structure is formed by a bond of silicon (Si) and oxygen (O), and which contains at least hydrogen as a substituent), a resist or the like can be used. Here, acryl, polyimide and a resist may be either photosensitive or non-photosensitive.

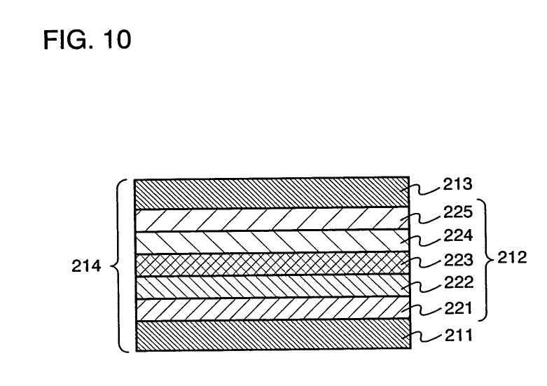

Next, the light-emitting layer 212 is formed over the first electrode 211 exposed in the opening portion of the bank layer 210. There is no limitation on the light-emitting layer 212 in particular. In this embodiment mode, as shown in FIG. 10, a first layer 221 formed by containing a substance which can assist in injecting an electron from the first electrode 211 to the light-emitting layer 212, a second layer 222 formed by containing a substance which transports an electron easily, a third layer 223 formed by containing a light-emitting substance, a fourth layer 224 formed by containing a substance which transports a hole easily, and a fifth layer 225 formed by containing a substance which can assist in injecting a hole from the second electrode 213 to the light-emitting layer 212 are sequentially stacked from the first layer 221; thus, the light-emitting layer 212 is formed.

Note that the substance which can assist in injecting an electron from the first electrode 211 to the light-emitting layer 212 is the same as the substance which can assist in injecting an electron from the second electrode 104 to the light-emitting layer 103 described in Embodiment Mode 1. The substance which transports an electron easily is the same as the substance which transports an electron easily described in Embodiment Mode 1. The light-emitting substance is the same as the light-emitting substance described in Embodiment Mode 1. Moreover, the substance which transports a hole easily is the same as the substance which transports a hole easily described in Embodiment Mode 1. Furthermore, the substance which can assist in injecting a hole from the second electrode 213 to the light-emitting layer 212 is the same as the substance which can assist in injecting a hole from the second electrode 102 to the light-emitting layer 103 described in Embodiment Mode 1.

Next, the second electrode 213 is formed over the light-emitting layer 212. There is no limitation on the materials of the second electrode 213 in particular, but in this embodiment mode, the second electrode 213 is formed by using a substance having high work function which is the same as that of the first electrode 102 in Embodiment Mode 1.

Next, the substrate 201 and a substrate 240 are bonded to each other and sealed with a sealant 241 so that the light-emitting element 214 is sealed inside. At this time, the sealed inside may be filled with an inert gas such as nitrogen or a resin having low moisture permeability, or may be vacuum.

Next, an FPC (Flexible Printed Circuit) 242 is attached to a terminal portion 206 provided over the substrate 201 with an anisotropic conductive adhesive agent 243.

Note that a driver circuit portion is not necessarily provided over the same substrate as the pixel portion as described above, and for example, a driver circuit portion may be provided for the outside of the substrate by utilizing an object (TCP) or the like in which an IC chip is mounted over the FPC in which a wiring pattern is formed.

Next, a process for stabilizing the lowering of luminance of the light-emitting element 214 is performed. Note that this step may be carried out in the same manner as the step (the step for applying forward voltage) described in Embodiment Mode 1.

Next, a process for decreasing voltage which is required to apply a certain amount of current to the light-emitting element 214 is performed. Note that this step may be carried out in the same manner as the step (the step for applying reverse voltage) described in Embodiment Mode 1.

The light-emitting device manufactured as described above is an object in which the lowering of light-emitting luminance depending on the passage of emission time is stabilized, and further, the increase of power consumption generated by the stabilization process is decreased.

Note that, in this embodiment mode, the process for stabilizing the lowering of luminance and the process for decreasing voltage which is required to apply a certain amount of current are performed after sealing; however, without being limited to this, these processes may be performed before sealing. The position of these processes is not limited in particular.

There is no limitation on the structure of the transistors 202 and 203 in particular, and the transistors may be a single gate transistor or a multi-gate transistor. The transistors may have a single drain structure or an LDD (Lightly Doped Drain) structure. The transistors also may have a staggered structure or a reverse staggered structure. Moreover, the transistors may be a transistor including a semiconductor layer containing a crystalline component as an active layer or a transistor including a semiconductor layer containing a non-crystalline component as an active layer. Here, a semi-amorphous semiconductor is also included in a semiconductor containing a crystalline component. A semi-amorphous semiconductor is described hereinafter. A semi-amorphous semiconductor has an intermediate structure between an amorphous structure and a crystalline structure (including a single crystalline and polycrystalline structure), a third state which is stable in a view of free energy, and a crystalline region having a short-range order and lattice distortion. In addition, at least a part of the film includes a crystal grain having a grain diameter of from 0.5 nm to 20 nm. The Raman spectrum shifts to the lower wave number side than 520 cm⁻¹. Diffraction peaks of (111) and (220) which are thought to be derived from Si crystalline lattice are observed by X-ray diffraction. At least 1 atomic % or more of hydrogen or halogen is contained in a semi-amorphous semiconductor for terminating a dangling bond. The semi-amorphous semiconductor is also referred to as a so-called microcrystal semiconductor. It is formed by glow discharge decomposition (plasma CVD) of a silicide gas. It is possible to use SiH₄, additionally, Si₂H₆, SiH₂Cl₂, SiHCl₃, SiCl₄, SiF₄ or the like as the silicide gas. The silicide gas may be diluted with H₂, or H₂ with one or more kinds of rare gas elements selected from He, Ar, Kr and Ne. Dilution ratio is in a range of from 2 times to 1000 times. Pressure is in a range of from 0.1 Pa to 133 Pa, and power frequency is from 1 MHz to 120 MHz, preferably, from 13 MHz to 60 MHz. The temperature for heating a substrate may be 300° C. or less, preferably, in a range of from 100° C. to 250° C. As for an impurity element in a film, impurities of atmospheric component such as oxygen, nitrogen, or carbon are preferably set to be 1×10²⁰ /cm³ or less, especially, the oxygen concentration is set to be 5×10¹⁹ /cm³ or less, preferably, 1×10¹⁹ /cm³ or less. Further, mobility of a TFT (a thin film transistor) using a semi-amorphous semiconductor is approximately from 1 m²/Vsec to 10 m²/Vsec.

[Embodiment Mode 3]

The light-emitting device manufactured according to Embodiment Mode 1 or Embodiment Mode 2 can be used, for example, as a display portion of an electronic device.

In this embodiment mode, a light-emitting device incorporated into a display portion of an electronic device, a circuit provided for a pixel portion of the light-emitting device and driving the same, and an electronic device in which the light-emitting device manufactured by applying the present invention is incorporated are described.

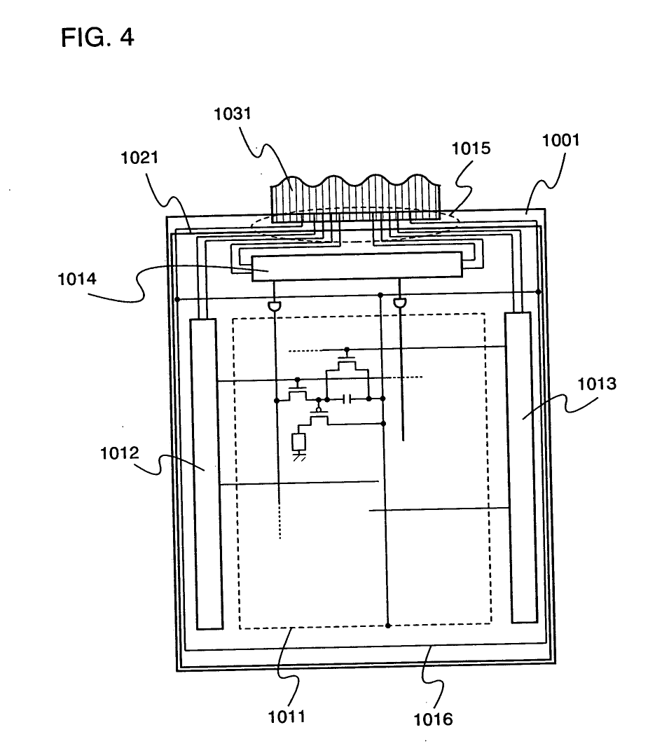

FIG. 4 is a top view of the light-emitting device in which an FPC is mounted. The light-emitting device of FIG. 4 is an object manufactured by a manufacturing method as shown in Embodiment Mode 2.

In FIG. 4, a first substrate 1001 and a second substrate 1021 are bonded so as to face each other. The first substrate 1001 is provided with a pixel portion 1011, a driver circuit portion 1012 for driving a first scanning line, a driver circuit portion 1013 for driving a second scanning line, a driver circuit portion 1014 for driving a source signal line, and a group of connection wires 1015 (surrounded by a dotted line). The driver circuit portions 1012, 1013 and 1014 are provided with a shift register, a buffer, a switch and the like. Moreover, the group of connection wires 1015 is connected to the FPC (Flexible Printed Circuit) 1031, an external input terminal, with an anisotropic conductive adhesive agent. Furthermore, a plurality of pixels constituted by including a light-emitting element and a circuit for driving the same are arranged in the pixel portion 1011. A signal such as a video signal, a clock signal, a start signal and a reset signal is transmitted from a controller to the driver circuit portions 1012, 1013 and 1014, a power supply line 1016 and the like through the FPC 1031. Then, a signal is transmitted from the driver circuit portions 1012, 1013 and 1014 and the power supply line 1016 to the pixel portion 1011.

Note that the driver circuit portion is not necessarily provided over the same substrate as that of the pixel portion 1011 as described above. For example, the driver circuit portion may be provided for the external of the substrate by utilizing an object (TPC) or the like in which an IC chip is mounted over the FPC in which a wiring pattern is formed.

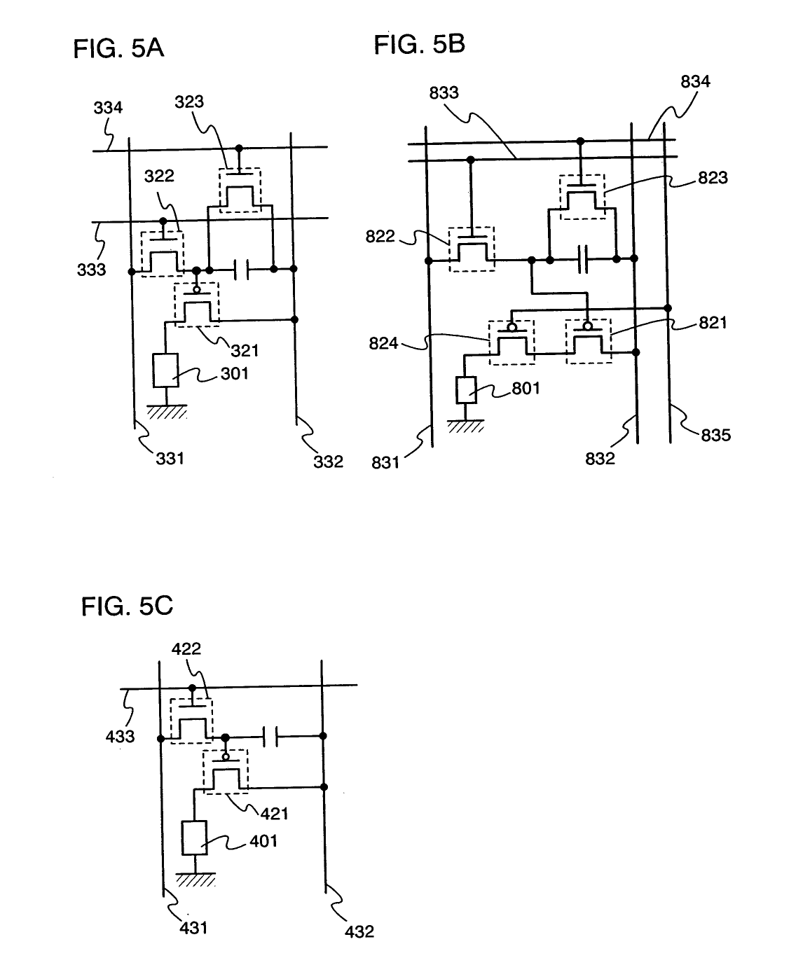

In the light-emitting device described above, a plurality of pixels constituted by including the light-emitting element and the circuit for driving the same are arranged in the pixel portion 1011. The circuit included in the pixel so as to drive the light-emitting element is described hereinafter with reference to FIGS. 5A to 5C. However, the configuration of the circuit for driving the light-emitting element is not limited to an object shown hereinafter.

As shown in FIG. 5A, a light-emitting element 301 is connected to a circuit for driving each light-emitting element. The each circuit includes a driving transistor 321 which determines an emission state or a non emission state of the light-emitting element 301 by a video signal, a switching transistor 322 which controls an input of the video signal, and an erasing transistor 323 which makes the light-emitting element 301 non emission state regardless of the video signal. Here, a source (or a drain) of the switching transistor 322 is connected to a source signal line 331, a source of the driving transistor 321 and a source of the erasing transistor 323 are connected to a current supply line 332 extended parallel to the source signal line 331, a gate of the switching transistor 322 is connected to a first scanning line 333, and a gate of the erasing transistor 323 is connected to a second scanning line 334 extended parallel to the first scanning line 333. In addition, the driving transistor 321 and the light-emitting element 301 are connected to each other in series. Note that, when an electrode which is included in the light-emitting element 301 and serves as an anode is connected to the driving transistor 321, a p-channel type transistor is used for the driving transistor 321. Alternatively, when an electrode which is included in the light-emitting element 301 and serves as a cathode is connected to the driving transistor 321, an n-channel type transistor is used for the driving transistor 321.

A driving method when the light-emitting element 301 emits light is described. As soon as the first scanning line 333 is selected within a writing period, the switching transistor 322 in which the gate thereof is connected to the first scanning line 333 turns ON. Then, the video signal inputted to the source signal line 331 is inputted to a gate of the driving transistor 321 through the switching transistor 322; and thus, current flows from the current supply line 332 toward the light-emitting element 301 to emit light. At this time, luminance of light is determined depending on the amount of current which flows toward the light-emitting element 301.

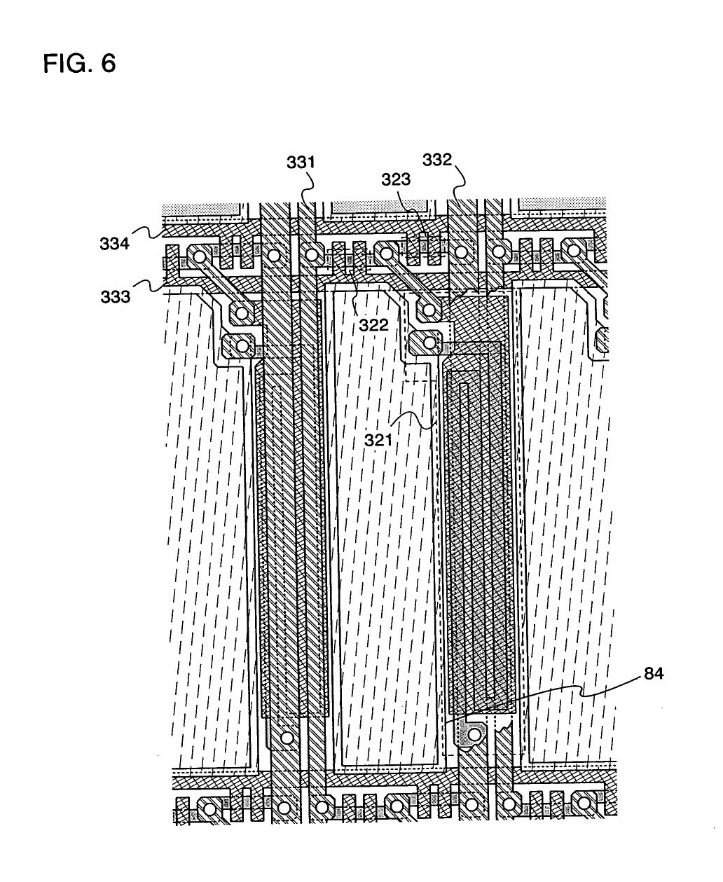

FIG. 6 is a top view of a pixel portion of a light-emitting device having a circuit shown in FIG. 5A. Reference numerals in FIG. 6 denotes the same objects as that of FIG. 5A. Moreover, in FIG. 6, the light-emitting element 301 is not shown and an electrode 84 of the light-emitting element 301 is shown.

Moreover, the configuration of the circuit connected to the each light-emitting element is not limited to an object described above, and for example, a configuration which is the same as that of FIG. 5B, FIG 5C or the like described hereinafter may be used.

Next, a circuit shown in FIG. 5B is described. As shown in FIG 5B, a light-emitting element 801 is connected to a circuit for driving each light-emitting element. The circuit includes a driving transistor 821 which determines an emission state or a non emission state of the light-emitting element 801 by a video signal, a switching transistor 822 which controls an input of the video signal, an erasing transistor 823 which makes the light-emitting element 801 non emission state regardless of the video signal, and a current control transistor 824 for controlling the amount of current which is supplied to the light-emitting element 801. Here, a source (or a drain) of the switching transistor 822 is connected to a source signal line 831, a source of the driving transistor 821 and a source of the erasing transistor 823 are connected to a current supply line 832 extended parallel to the source signal line 831, a gate of the switching transistor 822 is connected to a first scanning line 833, and a gate of the erasing transistor 823 is connected to a second scanning line 834 extended parallel to the first scanning line 833. In addition, the driving transistor 821 and the light-emitting element 801 are connected to each other in series by interposing the current control transistor 824 therebetween. A gate of the current control transistor 824 is connected to a power supply line 835. Further, the current control transistor 824 is constituted and controlled so that current flows in a saturated region of voltage-current (Vd-Id) characteristics. Accordingly, the amount of a current value which flows through the current control transistor 824 can be determined. Note that, when an electrode which is included in the light-emitting element 301 and serves as an anode is connected to the driving transistor 821, a p-channel type transistor is used for the driving transistor 821. Alternatively, when an electrode which is included in the light-emitting element 801 and serves as a cathode is connected to the driving transistor 821, an n-channel type transistor is used for the driving transistor 821.

A driving method when the light-emitting element 801 emits light is described. As soon as the first scanning line 833 is selected within a writing period, the switching transistor 822 in which the gate thereof is connected to the first scanning line 833 turns ON. Next, the video signal inputted to the source signal line 831 is inputted to a gate of the driving transistor 821 through the switching transistor 822. Then, current flows from the current supply line 832 toward the light-emitting element 801 through the driving transistor 821 and the current control transistor 824 which is made to turn ON by a signal from the power supply line 835; and thus, light is emitted. At this time, the amount of the current which flows toward the light-emitting element is determined depending on the current control transistor 824.

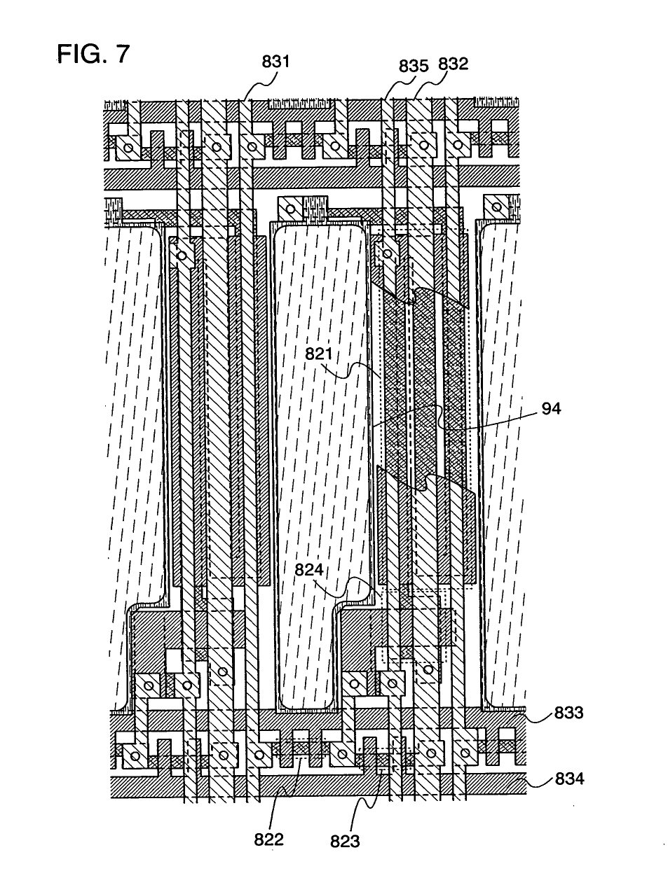

FIG. 7 is a top view of a pixel portion of a light-emitting device which has a circuit shown in FIG. 5B and which is to form one electrode among a pair of electrodes of a light-emitting element. Reference numerals in FIG. 7 denote the same objects as that of FIG. 6. Moreover, in FIG. 7, the light-emitting element 801 is not shown and an electrode 94 of the light-emitting element 801 is shown.

Next, a circuit shown in FIG 5C is described. A circuit for driving each light-emitting element is connected to a light-emitting element 401. The each circuit includes a driving transistor 421 which determines an emission state or a non emission state of the light-emitting element 401 by a video signal and a switching transistor 422 which controls an input of the video signal. Here, a source (or a drain) of the switching transistor 422 is connected to a source signal line 431, a source of the driving transistor 421 is connected to a current supply line 432 extended parallel to the source signal line 431, and a gate of the switching transistor 422 is connected to a scanning line 433. In addition, the driving transistor 421 and the light-emitting element 401 are connected to each other in series. Note that, when an electrode which is included in the light-emitting element 401 and serves as an anode is connected to the driving transistor 421, a p-channel type transistor is used for the driving transistor 421. Alternatively, when an electrode which is included in the light-emitting element 401 and serves as a cathode is connected to the driving transistor 421, an n-channel type transistor is used for the driving transistor 421.

A driving method when the light-emitting element 401 emits light is described. As soon as the scanning line 433 is selected within a writing period, the switching transistor 422 in which the gate thereof is connected to the scanning line 433 turns ON. Next, the video signal inputted to the source signal line 431 is inputted to a gate of the driving transistor 421 through the switching transistor 422; and thus, current flows from the current supply line 432 toward the light-emitting element 401 to emit light. At this time, luminance of light is determined depending on the amount of current which flows toward the light-emitting element 401.

The light-emitting device described above may be an object of mono-color display or an object of full-color display.

In the case of carrying out full-color display, for example, light-emitting layers having different emission wavelength ranges are formed in each pixel; and thus, a full-color display can be carried out. Typically, light-emitting layers which correspond to each color of R (red), G (green) and B (blue) are formed. In this case, by forming a structure that a filter (colored layer) which transmits light in the emission wavelength range is provided in the light emission side of the pixel, color purity can be improved and a pixel portion can be prevented from being a mirror surface (glare). By providing the filter (colored layer), a circularly polarizing plate or the like which is conventionally thought to be required can be omitted, and the loss of light emitted from the light-emitting layer can be eliminated. Moreover, the change of color tone which occurs in the case where the pixel portion (display screen) is viewed from an oblique direction can be further eliminated.

Moreover, a structure in which a light-emitting layer exhibits monochromatic or white light can be employed, in addition to the structure in which color display is performed by providing the light-emitting layers which correspond to each color as described above. In case of using a white light-emitting material, color display can be performed by employing a structure that a filter (a colored layer) which transmits light having a certain wavelength is provided in the light emission side of the pixel.

Further, to form the light-emitting layer which emits white light, for example, Alq₃, Alq₃ doped partly with Nile red, Alq₃, p-EtTAZ and TPD (aromatic diamine) are sequentially stacked by using a vapor deposition method; accordingly, white color can be obtained. In the case where the light-emitting layer is formed by an application method using a spin coat, the light-emitting layer is preferably formed in accordance with the procedure, that is, a material is applied and baked by vacuum heating. For example, poly(ethylenedioxythiophene)/poly(styrenesulfonate) water solution (PEDOT/PSS) is entirely applied and baked, then, a polyvinylcarbazole (PVK) solution doped with pigment (1,1,4,4-tetraphenyl-1,3-butadiene (TPB), 4-dicyanomethylene-2-methyl-6-(p-dimethylamino-styryl)-4H-pyran (DCM1), Nile red, coumarin 6 or the like) may be entirely applied and baked thereover.

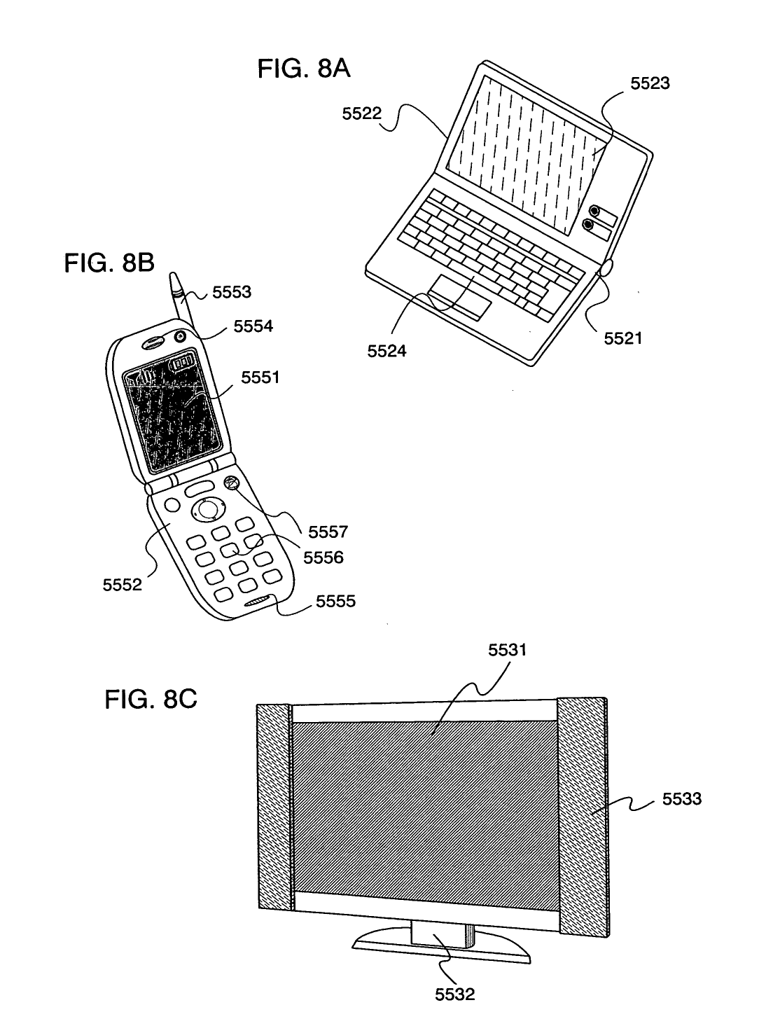

FIGS. 8A to 8C show one embodiment of the electronic device mounted with the light-emitting device to which the invention is applied.

FIG. 8A shows a laptop personal computer manufactured by applying the invention. The personal computer includes a main body 5521, a chassis 5522, a display portion 5523, a keyboard 5524 and the like. The personal computer can be completed by incorporating the light-emitting device having the light-emitting element of the invention as a display portion.

FIG. 8B shows a cellular phone manufactured by applying the invention. In a main body 5552, a display portion 5551, an audio output portion 5554, an audio input portion 5555, operation switches 5556 and 5557, an antenna 5553 and the like are provided. The cellular phone can be completed by incorporating the light-emitting device having the light-emitting element of the invention as a display portion.

FIG. 8C is a television set manufactured by applying the invention. The television set includes a display portion 5531, a chassis 5532, a speaker 5533 and the like. The television set can be completed by incorporating the light-emitting device of the invention as a display portion.

The light-emitting device of the invention is especially suitable to be used as a display portion of various electronic devices, as described above.

Note that the personal computer, the cellular phone and the like are described in this embodiment mode, but besides, the light-emitting device having the light-emitting element of the invention may be mounted on a car navigation system, a lightning system or the like.

The electronic devices to which the invention is applied as described above can provide a favorable display image. In addition, the electronic devices to which the invention is applied can be driven with low power consumption.

[Embodiment 1]

A result of the measurement in which characteristics of a light-emitting device manufactured by applying the present invention is described.

First, a light-emitting element used for evaluation is described. The light-emitting element used for the evaluation is a rectifying element having a layer formed from tris(8-quinolinolato)aluminum (abbreviated Alq₃) to have a 100 nm film thickness over an electrode formed from indium tin oxide (ITO) and having an electrode formed from aluminum over the layer formed from Alq₃.

Next, a measurement method is described. Note that voltage indicates forward voltage unless there is no description in particular. Moreover, in this embodiment, an emission spectrum of the light-emitting element is measured with a fluorescence spectrophotometer. The variation of a value obtained by integrating an emission spectrum corresponds to the variation of a photon number, and the variation of the photon number further corresponds to the variation of luminance. Therefore, the variation of luminance can be indirectly examined by examining the variation of an integral value of the emission spectrum.

First, the integral value of the emission spectrum at a current of 1 mA and the voltage required to apply the current of 1 mA are measured.

Next, the current of 1 mA is applied by applying forward voltage to the light-emitting element for a certain period of time (in this embodiment, for 1,800 seconds). Through the period, the integral value of the emission spectrum at a current of 1 mA and the voltage required to apply the current of 1 mA are measured once every 600 minutes.

Moreover, reverse voltage of 10 V is applied to the light-emitting element for a certain period of time (in this embodiment, for 1,200 seconds). Through the period, the integral value of the emission spectrum at a current of 1 mA and the voltage (forward voltage) required to apply the current of 1 mA are measured once every 300 minutes.

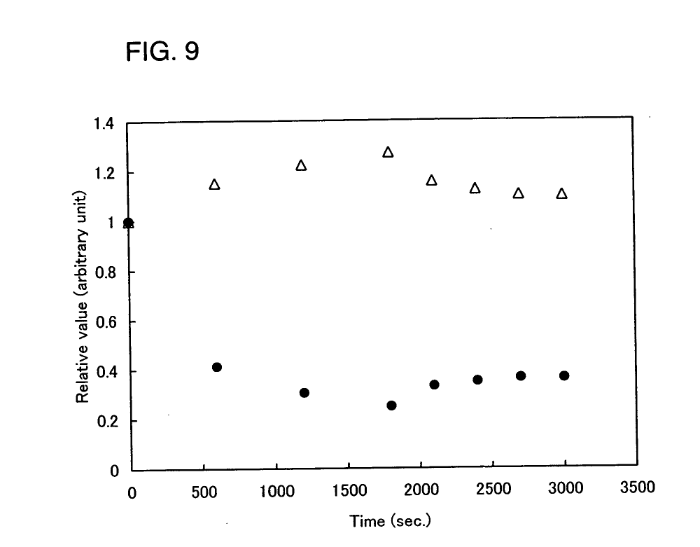

FIG. 9 shows a result measured as described above. Note that a horizontal axis shows a passage of time (a unit of time: second) from the beginning of the measurement. Alternatively, a vertical axis shows a relative value (an arbitrary unit) of the integral value of the emission spectrum at a current of 1 mA and a relative value (an arbitrary unit) of the voltage required to apply the current of 1 mA. Note that the relative value is a value obtained on the basis of the integral value of the emission spectrum at a current of 1 mA and the voltage required to apply the current of 1 mA, each at the beginning of the measurement.

Plots of a black dot (•) in FIG. 9 shows that, in the period from 0 to 1,800 seconds (when the forward voltage is applied), the integral value of the emission spectrum at a current of 1 mA decreases with time, and especially decreases drastically in the period of from 0 to 600 seconds. It is also understood that the decrease of the integral value of the emission spectrum becomes less after 600 seconds. Moreover, plots of a white triangle (Δ) in FIG. 9 shows that the voltage required to apply the current of 1 mA becomes gradually larger with time.

Moreover, the integral value of the emission spectrum at a current of 1 mA remains almost the same beyond time in the period of from 1,800 to 3,000 seconds (when the reverse voltage is applied). On the other hand, the voltage required to apply the current of 1 mA becomes gradually smaller with time.

Through the above, the voltage required to apply the current of 1 mA increased by a stabilizing process (application of the forward voltage) can be decreased by applying the reverse voltage in the state where the stability of the lowering of luminance with time is maintained.

This application is based on Japanese Patent Application serial no. 2004-091938 field in Japan Patent Office on Mar. 26, 2004, the entire contents of which are hereby incorporated by reference.

1. A method for manufacturing a light-emitting device comprising:
applying a reverse voltage after applying a forward voltage to a light-emitting element which shows a rectifying action to reduce a power consumption of the light-emitting device.

2. A method for manufacturing a light-emitting device according to claim 1, wherein the reverse voltage is applied for 6×10¹ to 6×10⁵ seconds continuously.

3. A method for manufacturing a light-emitting device according to claim 1, wherein the light-emitting device is incorporated in at least one selected from the group consisting of a personal computer, a cellular phone, and a television.

4. A method for manufacturing a light-emitting device comprising:
applying a forward voltage to a light-emitting element which shows a rectifying action until a luminance of the light-emitting element is to be from 80 to 95% of initial luminance; and
applying a reverse voltage to the light-emitting element after applying the forward voltage.

5. A method for manufacturing a light-emitting device according to claim 4, wherein the reverse voltage is applied for 6×10¹ to 6×10⁵ seconds.

6. A method for manufacturing a light-emitting device according to claim 4, wherein the light-emitting device is incorporated in at least one selected from the group consisting of a personal computer, a cellular phone, and a television.

7. A method for manufacturing a light-emitting device comprising:
applying a forward voltage to a light-emitting element which shows a rectifying action for 6×10¹ to 6×10⁵ seconds; and
applying a reverse voltage to the light-emitting element after applying the forward voltage.

8. A method for manufacturing a light-emitting device according to claim 7, wherein the reverse voltage is applied for 6×10¹ to 6×10⁵ seconds.

9. A method for manufacturing a light-emitting device according to claim 7, wherein the light-emitting device is incorporated in at least one selected from the group consisting of a personal computer, a cellular phone, and a television.

10. A method for manufacturing a light-emitting device comprising:
forming a transistor over a substrate;
forming a light-emitting element which shows a rectifying action and is electrically connected to the transistor; and
applying a reverse voltage after applying a forward voltage to the light-emitting element to reduce a power consumption of the light-emitting device.

11. A method for manufacturing a light-emitting device according to claim 10, wherein the reverse voltage is applied for 6×10¹ to 6×10⁵ seconds.

12. A method for manufacturing a light-emitting device according to claim 10, wherein the light-emitting device is incorporated in at least one selected from the group consisting of a personal computer, a cellular phone, and a television.

13. A method for manufacturing a light-emitting device comprising:
forming a transistor over a substrate;
forming a light-emitting element which shows a rectifying action and is electrically connected to the transistor; and
applying a forward voltage to the light-emitting element until a luminance of the light-emitting element is to be from 80 to 95% of initial luminance; and
applying a reverse voltage to the light-emitting element after applying the forward voltage.

14. A method for manufacturing a light-emitting device according to claim 14, wherein the reverse voltage is applied for 6×10¹ to 6×10⁵ seconds.

15. A method for manufacturing a light-emitting device according to claim 14, wherein the light-emitting device is incorporated in at least one selected from the group consisting of a personal computer, a cellular phone, and a television.

16. A method for manufacturing a light-emitting device comprising:
forming a transistor over a substrate;
forming a light-emitting element which shows a rectifying action and is electrically connected to the transistor;
applying a forward voltage to the light-emitting element for 6×10¹ to 6×10⁵ seconds; and
applying a reverse voltage to the light-emitting element after applying the forward voltage.

17. A method for manufacturing a light-emitting device according to claim 16, wherein the reverse voltage is applied for 6×10¹ to 6×10⁵ seconds.

18. A method for manufacturing a light-emitting device according to claim 16, wherein the light-emitting device is incorporated in at least one selected from the group consisting of a personal computer, a cellular phone, and a television.
